(19) United States
(12) Patent Application Publication
(10) Pub. No.: US 2004/0171279 A1
(43) Pub. Date: Sep. 2, 2004

(54) Method of low-temperature oxidation of silicon using nitrous oxide

(75) Inventor: Yoshi Ono, Camas, WA (US)

Correspondence Address: David C. Ripma, Patent Counsel, Sharp Laboratories of America, Inc., 5750 NW Pacific Rim Boulevard, Camas, WA, 98607, US

(73) Assignee: Sharp Laboratories of America Inc.

(21) Appl. No.: 10/376,775

(22) Filed: Feb. 27, 2003

(51) Int. Cl. H01L 21/31; H01L 21/469

(52) U.S. Cl. 438/770

(57) ABSTRACT

A method of low-temperature oxidation of a silicon substrate includes placing a silicon wafer in a vacuum chamber; maintaining the silicon wafer at a temperature of between about 25° C. and 600° C.; introducing N₂O gas into the vacuum chamber; dissociating the N₂O gas into oxygen(¹D) with a xenon laser generating light at a wavelength of about 172 nm and flowing the oxygen(¹D) over the silicon wafer; and forming an oxide layer on at least a portion of the silicon wafer.

### RELATED APPLICATION

This Application is related to Ser. No. 10/164,919, filed Jun. 4, 2002, for A method of forming a high quality gate oxide at low temperatures.

### FIELD OF THE INVENTION

This invention relates to the fabrication of integrated circuits on silicon, and specifically to a low temperature, high quality silicon dioxide layer formed from the oxidation of silicon.

### BACKGROUND OF THE INVENTION

The conventional technique for the oxidation of silicon requires high temperatures, e.g., greater than 800° C., for long periods of time in an oxidizing ambient such as O₂, N₂O, or NO. During such oxidation, a diffusion of IC fabrication components occurs within the substrate, requiring that fabrication sequences be tailored to accommodate this diffusion. The capability to perform an oxidation at much lower temperatures, without sacrificing film quality, would be a tremendous benefit to the industry. The oxidation rate on (100) silicon, is practically the same as for (111) silicon so this oxidation can immediately address the need for conformal oxidation for shallow trench isolation. A low temperature oxidation can also provide a gate oxide for conventional CMOS devices, replacing high temperature thermal oxides.

An efficient method of oxidizing silicon at low temperatures for manufacturing purposes currently does not exist. There are known methods of oxidizing silicon at low temperatures such as plasma oxidation or oxidation with a radial slot line antennae. These methods, however, produce large quantities of ions, as well as radicals, which can damage the silicon surface and degrade the oxide quality.

Nayer et al. report the combination of UV and ozone to generate oxygen radicals, however, the atmospheric pressure used in their system allows O(¹D) to be deactivated by collisions to the O(³P) state. Thus the results they obtained are severely handicapped by the lack of the O(¹D). Nevertheless, enhanced oxidation rates and good stoichiometric oxide were reported. Atmospheric Pressure, Low Temperature (<500° C.) UV/Ozone Oxidation of Silicon, Electronics Letters, 26, 205 (1990).

Watanabe et al., Controlling the concentration and position of nitrogen in ultrathin oxynitride films formed by using oxygen and nitrogen radicals, Appl. Phys. Lett. 76, 2940 (2000), describes use of an electron cyclotron resonance plasma to produce oxygen and nitrogen radicals.

Saito et al., Advantage of Radical Oxidation for Improving Reliability of Ultra-Thin Gate Oxide, 2000 Symposium on VLSI Technology, T18-2, (2000), describes generation of oxygen radicals by microwave-excited Kr/O₂ plasma.

Hirayama et al., Low Temperature Growth of High-Integrity Silicon Oxide Films by Oxygen Radical Generated in High Density Krypton Plasma, IEDM Tech. Dig. p249, (1999), also describes excitement of Kr/O₂ by microwaves.

Coulter et al., Non-thermal SiO₂ film growth on Si(100) using laser-generated O(¹D) and O(³P), AVS Symposium 2001, describes use of a laser to generate atomic oxygen to oxidize silicon.

### SUMMARY OF THE INVENTION

A method of low-temperature oxidation of a silicon substrate includes placing a silicon wafer in a vacuum chamber; maintaining the silicon wafer at a temperature of between about 25° C. and 600° C.; introducing N₂O gas into the vacuum chamber; dissociating the N₂O gas into oxygen(¹D) with a xenon laser generating light at a wavelength of about 172 nm and flowing the oxygen(¹D) over the silicon wafer; and forming an oxide layer on at least a portion of the silicon wafer.

It is an object of the invention to provide a low-temperature oxidation of silicon.

Another object of the invention is to provide for oxidation of silicon with oxygen (¹D).

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 is a schematic representation of the apparatus used to achieve the low temperature oxidation in the method of the invention.

FIG. 2 is a graph depicting oxide thickness as a function of time using the method of the invention.

FIG. 3 is a graph depicting oxide thickness as a function of chuck temperature.

### DETAILED DESCRIPTION OF THE PREFERRED EMBODIMENTS

The method of the invention generates large quantities of a radical oxygen atom, specifically in the O(¹D) metastable state. It is known that O(¹D) may be produced by photodissociation of N₂O. N₂O irradiated with wavelengths less than 195 nm produces O(¹D) in a simple photodissociation step where N₂ and O are produced. By virtue of the fact that O(¹D) state is of higher energy than the ground O(³P) state, O(¹D) oxidizes silicon faster and with greater efficiency than will O(IP). The method of the invention in the related application described the use of O₂/O₃ as the source gas for oxygen. The method of the invention herein uses N₂O as the source gas, which produces an oxide layer, but which requires a longer time in which to grow the oxide layer. Thus the method of the invention provides a slower growing oxide layer and is useful in those instances where it is desirable to extend the oxide growth period.

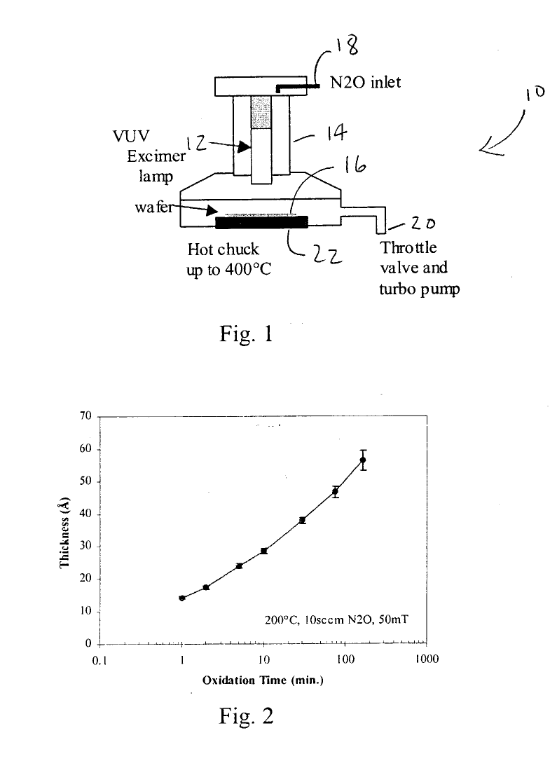

The apparatus used in the method of the invention is depicted in FIG. 1, generally at 10. An excimer lamp 12, which emits light at a wavelength of 172 nm is placed in a vacuum chamber 14 above the surface of silicon wafer 16 that is to be oxidized. Excimer lamp 12 is a xenon-based lamp and is commercially available at a reasonable cost. One such lamp is a Xeradex® lamp produced by Osram Sylvania.

A steady flow of N₂O is introduced into chamber 14 through inlet 18. The pressure in chamber 14 is controlled by a throttle valve 20, located between the chamber and the pump system. Wafer 16 sits on a heated chuck 22, capable of reaching temperatures of up to about 350° C. The thermal coupling between the wafer and chuck is poor, so the actual wafer temperature may be lower than 300° C. when the chuck temperature is set at 350° C. Chamber pressure is controlled to a range between about 20 mTorr. to 1 Torr. The flow of N₂O is regulated to be between about 5 sccm and 50 sccm.

The amount of the oxygen in the (¹D) state is a function of the amount of N₂O introduced into the chamber, the intensity of the light from the excimer lamp, and the duration of the existence of O(¹D) near the wafer surface. The longer the exposure to this environment, the thicker the resulting oxide on the wafer. The thickness of an oxide layer fabricated at a wafer temperature of 200° C., a N₂O flow of 10 sccm and a chamber pressure of 50 mTorr, is shown in FIG. 2.

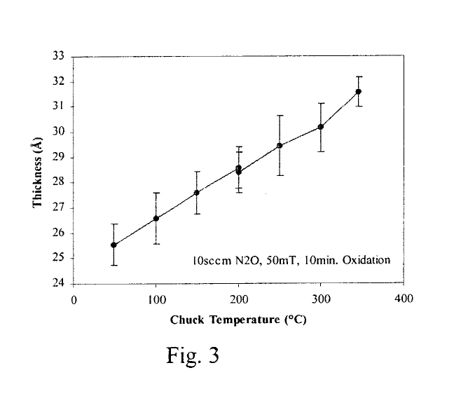

The oxidation of silicon with the O(¹D) radical is not highly temperature dependent and substantial oxides may be generated even at room temperature. At elevated temperatures, a small enhancement to the oxidation rate is seen. The temperature dependence for a ten minute oxidation, at various temperatures, is shown in FIG. 3. Because of the chuck design, the wafer does not reach the same temperature as the chuck. The temperature of the wafer may be as much as 50° C. to 100° C. cooler than the chuck set point at a chuck set point of 400° C. As shown by FIGS. 2 and 3, an oxide layer having a thickness of between about 15 Å and 50 Å may be formed on a wafer in a time period of between about one minute to 100 minutes, depending on wafer temperature, chamber pressure and N₂O flow.

With the advancement in excimer lamp technology, the use of alternate wavelengths are possible. Other excimers produce light at 126 nm, 146 nm, 222 nm, and 308 nm but not as efficiently as the Xe₂ at 172 nm.

The current shape of the lamp can be altered to take on a shape more efficient for wafer or gas volume illumination. In addition, multiple lamps of the current type can be used and oriented differently to achieve higher photon flux.

Thus, a method for low temperature oxidation of silicon using nitrous oxide has been disclosed. It will be appreciated that further variations and modifications thereof may be made within the scope of the invention as defined in the appended claims.

I claim:

1. A method of low-temperature oxidation of a silicon substrate comprising:
placing a silicon wafer in a vacuum chamber;
maintaining the silicon wafer at a temperature of between about 25° C. and 600° C.;
introducing N₂O gas into the vacuum chamber;
dissociating the N₂O gas into oxygen(¹D) with a xenon laser generating light at a wavelength of about 172 nm and flowing the oxygen(¹D) over the silicon wafer; and
forming an oxide layer on at least a portion of the silicon wafer.

2. The method of claim 1 which further includes maintaining the vacuum chamber at a pressure of between about 20 mTorr. and one Torr.

3. The method of claim 1 wherein said introducing N₂O gas in the vacuum chamber includes providing a gas flow rate of between about 5 sccm and 50 sccm.

4. The method of claim 1 wherein said maintaining includes maintaining the wafer in the vacuum chamber in contact with oxygen(¹D) for between about one minute and 100 minutes.

5. The method of claim 1 which includes forming an oxide layer on a silicon wafer having thickness of between about 15 Å to 50 Å in a time period of between about one minute to 100 minutes.

6. A method of low-temperature oxidation of a silicon substrate comprising:
placing a silicon wafer in a vacuum chamber having a heatable wafer chuck therein;
maintaining the silicon wafer at a temperature of between about 25° C. to 600° C.;
introducing N₂O gas in the vacuum chamber;
dissociating the N₂O gas into radical oxygen(¹D) with a xenon laser generating light at a wavelength of about 172 nm and flowing the radical oxygen(¹D) over the silicon wafer; and
forming an oxide layer on at least a portion of the silicon wafer in a time period of between about one minute to 100 minutes.

7. The method of claim 6 which further includes maintaining the vacuum chamber at a pressure of between about 20 mTorr. and one Torr.

8. The method of claim 6 wherein said introducing N₂O gas in the vacuum chamber includes providing a gas flow rate of between about 5 sccm and 50 sccm.

9. The method of claim 7 which includes forming an oxide layer on a silicon wafer having thickness of between about 15 Å to 50 Å.

10. A method of low-temperature oxidation of a silicon substrate comprising:
placing a silicon wafer in a vacuum chamber having a heatable chuck which is heatable to a temperature of at least about 350° C.;
maintaining the silicon wafer at a temperature of between about 25° C. and 600° C.;
introducing N₂O gas into the vacuum chamber;
dissociating the N₂O gas into radical oxygen(¹D) with a xenon laser generating light at a wavelength of about 172 nm and flowing the radical oxygen(¹D) over the silicon wafer for a time period of between about one minute and 100 minutes; and
forming an oxide layer on at least a portion of the silicon wafer having thickness of between about 15 Å to 50 Å.

11. The method of claim 10 which further includes maintaining the vacuum chamber at a pressure of between about 20 mTorr. and one Torr.

12. The method of claim 10 wherein said introducing N₂O gas in the vacuum chamber includes providing a gas flow rate of between about 5 sccm and 50 sccm.
